(19) United States
(12) Patent Application Publication
(10) Pub. No.: US 2016/0062823 A1
(43) Pub. Date: Mar. 3, 2016

(54) ERROR DETECTING DEVICE AND ERROR DETECTING METHOD

(71) Applicant: FUJITSU LIMITED, Kawasaki-shi (JP)

(72) Inventor: Shunji Miyazaki, Kawasaki (JP)

(21) Appl. No.: 14/745,987

(22) Filed: Jun. 22, 2015

(30) Foreign Application Priority Data
Aug. 28, 2014 (JP) 2014-174475

(51) Int. Cl. G06F 11/10; H03M 13/15

(52) U.S. Cl. CPC G06F 11/1004; H03M 13/159

(57) ABSTRACT

An error detecting device includes a memory that stores therein first remainders corresponding to a plurality of bit positions p×P (p is an integer equal to or greater than zero) at a predetermined bit interval P among all of remainders obtained by dividing monomials, which correspond to the respective bit positions in a bit string represented by a polynomial, by a generator polynomial for generating an error detecting code, and a processor configured to acquire, from the memory, the first remainders corresponding to p×P of p×P+q (q is an integer equal to or greater than zero and smaller than P) representing normal bit positions of bits of 1 among all of the bits of an input bit string, obtain a cumulative addition result by shifting each of the acquired first remainders by q bits to obtain shift results.

### CROSS-REFERENCE TO RELATED APPLICATION

This application is based upon and claims the benefit of priority of the prior Japanese Patent Application No. 2014-174475, filed on Aug. 28, 2014, the entire contents of which are incorporated herein by reference.

### FIELD

The embodiments discussed herein are related to an error detecting device and an error detecting method.

### BACKGROUND

In data communication systems requested to transmit data without errors or in storage devices or the like requested to read data without errors, “error detecting codes” are used to detect transmission errors, read errors, or the like.

A “cyclic redundancy check (CRC) code” is one of the error detecting codes. In a data communication system that detects an error by using the CRC code, a transmission side adds an L-bit remainder, which is obtained by dividing a polynomial corresponding to a K′-bit information bit string by a generator polynomial for generating the CRC code, to the information bit string to form a K-bit encoded bit string, and transmits the K-bit encoded bit string to a reception side. Therefore, the information bit size after the error detection coding is “K=K′+L”, and a remainder of a division of the K-bit encoded bit string by the generator polynomial is “zero (0)”. K′ is an information bit size of one block, that is, a block size. The L-bit remainder added to each block of the information bit is referred to as a “parity bit”.

The reception side divides the received encoded bit string by the generator polynomial, and detects an error in the received encoded bit string by determining that “there is no error” when the remainder is “0” and determining that “there is an error” when the remainder is “other than 0”.

For example, a polynomial B(x) of the K′-bit information bit string of “b=(a₀, . . . , a_{K′-2}, a_{K′-1})” is represented by Expression (1).

B(x)=a₀x^{K′}+ . . . +a_{K′-2}x+a_{K′-1} (1)

Further, a generator polynomial G(x) is represented by Expression (2).

G(x)=g₀x^{L}+ . . . +g_{L-2}x+g_{L-1} (2)

A remainder R_{crc}(x) of a division of the polynomial B(x) represented by Expression (1) by the generator polynomial G(x) is represented by Expression (3). The remainder R_{crc}(x) corresponds to a parity bit.

R_{crc}(x)=[x^{L}B(x)] mod G(x)=a_{K′}x^{L-1}+ . . . +a_{K-2}x+a_{K-1} (3)

If R_{crc}(x) whose bit position is adjusted is added to B(x), a polynomial A(x) represented by Expression (4) is obtained. A(x) corresponds to a polynomial that represents the K-bit encoded bit string of “a=(a₀, . . . , a_{K-2}, a_{K-1})” obtained through error detection coding.

A(x)=x^{L}B(x)+R_{crc}(x)=a₀x^{K}+ . . . +a_{K-2}x+a_{K-1} (4)

The transmission side transmits the encoded bit string represented by the polynomial A(x) to the reception side.

In this case, a remainder of a division of A(x) by G(x) is “0”. Therefore, assuming that a quotient polynomial of a division of A(x) by G(x) is denoted by Q(x), A(x) is represented by Expression (5).

A(x)=Q(x)G(x) (5)

Therefore, the reception side calculates a remainder R̂(x) of a division of a received encoded bit string Â(x) by the generator polynomial G(x) in accordance with Expression (6).

\hat{R}(x)=\hat{A}(x)mod G(x) (6)

The reception side determines that “there is no error” in Â(x) when R̂(x) is “0”, and determines that “there is an error” in Â(x) when R̂(x) is “other than 0”.

Incidentally, as a first related technology, there is a known error detecting device that, with respect to an encoded bit string in which a sequence is randomized through an interleaving process, is capable of detecting an error in the encoded bit string without performing a deinterleaving process to change the sequence. In the error detecting device, a remainder of a division of a polynomial, which corresponds to each of bit positions in the information bit string before the interleaving process (that is, normal bit positions), by the generator polynomial is calculated and stored in a memory in advance. Then, each of bits in the bit string is randomly input, and bit position information indicating the normal bit position of each of the bits is also input. A remainder corresponding to the normal bit position of each of the bits other than zero among all of the bits in the input bit string is acquired from the memory, and the acquired remainders are cumulatively added. If a cumulative addition result is “0”, it is determined that “there is no error” in the input bit string. If the cumulative addition result is “other than 0”, it is determined that “there is an error” in the input bit string. Namely, a cumulative addition result of the remainders corresponding to the normal bit positions of the bits other than zero among all of the bits in the input bit string corresponds to R̂(x) in Expression (6).

Further, as a second related technology, there is a known error detecting device capable of reducing a size of the memory in the first related technology. In the error detecting device, assuming that a predetermined bit interval is denoted by “P”, only remainders corresponding to bit positions of “n×P” (n=1, 2, . . . ) among the normal bit positions are stored in the memory. A remainder corresponding to each of the bit positions of “n×P” among the normal bit positions in the input bit string is obtained from the memory, similarly to the first related technology. Meanwhile, a remainder corresponding to each of bit positions of “n×P+k” (0≦k<P) among the normal bit positions is calculated by shifting each of the remainders corresponding to the bit positions of “n×P” by k bits and dividing a shift result by the generator polynomial. Then, all of the remainders acquired from the memory and all of the remainders calculated by the shift and the division are cumulatively added, and presence or absence of an error in the input bit string is determined based on a cumulative addition result, similarly to the first related technology.

Examples of related-art are described in Japanese Patent No. 5126230, in International Publication Pamphlet No. 2009/019763, in International Publication Pamphlet No. 2008/023684, in Japanese Laid-open Patent Publication No. 2009-136025, in Japanese Laid-open Patent Publication No. 2005-006188, in United States Patent Publication No. 2010/0138725, and in United States Patent Publication No. 2010/0198892

However, in the second related technology, remainders that are not stored in the memory, that is, remainders corresponding to the bit positions of “n×P+k” are calculated by dividing the shift result; therefore, a remainder is calculated for each of the bit positions of “n×P+k”. Consequently, in the second related technology, the number of calculations of remainders increases with an increase in the block size, resulting in the increased processing load for error detection.

### SUMMARY

According to an aspect of an embodiment, an error detecting device includes a memory that stores therein first remainders corresponding to a plurality of bit positions p×P (p is an integer equal to or greater than zero) at a predetermined bit interval P among all of remainders obtained by dividing monomials, which correspond to the respective bit positions in a bit string represented by a polynomial, by a generator polynomial for generating an error detecting code, and a processor configured to receive each of bits of an input bit string, receive normal bit positions of the respective bits, acquire, from the memory, the first remainders corresponding to p×P of p×P+q (q is an integer equal to or greater than zero and smaller than P) representing the normal bit positions of bits of 1 among all of the bits of the input bit string, obtain a cumulative addition result by shifting each of the acquired first remainders by q bits to obtain shift results, and then cumulatively adding all of the shift results corresponding to all of the bits of 1 among all of the bits of the input bit string, perform a remainder calculation to obtain a second remainder by dividing the cumulative addition result by the generator polynomial, and determine presence or absence of an error in the input bit string on the basis of the second remainder.

According to another aspect of an embodiment, an error detecting device includes a memory that stores therein first remainders corresponding to a plurality of bit positions p×P (p is an integer equal to or greater than zero) at a predetermined bit interval P among all of remainders obtained by dividing monomials, which correspond to the respective bit positions in a bit string represented by a polynomial, by a generator polynomial for generating an error detecting code, and a processor configured to receive each of bits of an input bit string, receive normal bit positions of the respective bits, acquire, from the memory, the first remainders corresponding to p×P of p×P+q (q is an integer equal to or greater than zero and smaller than P) representing the normal bit positions of bits of 1 among all of the bits of the input bit string, perform, for each q, a remainder calculation to obtain a second remainder by cumulatively adding the acquired first remainders for each q to obtain a cumulative addition result for each q, shifting the cumulative addition result by q bits to obtain a shift result, and dividing the shift result by the generator polynomial, obtain a third remainder by adding all of the second remainders corresponding to all q, and determine presence or absence of an error in the input bit string on the basis of the third remainder.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a functional block diagram illustrating an example of an error detecting device of a first embodiment;

FIG. 2 is a diagram illustrating an example of a remainder table of the first embodiment;

FIG. 3 is a flowchart for explaining a process performed by the error detecting device of the first embodiment;

FIG. 4 is a functional block diagram illustrating an example of an error detecting device of a second embodiment;

FIG. 5 is a flowchart for explaining a process performed by the error detecting device of the second embodiment;

FIG. 6 is a functional block diagram illustrating an example of an error detecting device of a third embodiment; and

FIG. 7 is a diagram illustrating a hardware configuration example of the error detecting device.

### DESCRIPTION OF EMBODIMENTS

Preferred embodiments of the present invention will be explained with reference to accompanying drawings. The error detecting device and the error detecting method of the disclosed technology are not limited to the embodiments below. In each of the embodiments, components having the same functions and steps of the same processes are denoted by the same reference numerals and symbols, and the same explanation will not be repeated.

### [a] First Embodiment

### Operation of Error Detecting Device

A remainder calculation to obtain a remainder R(x) by dividing the polynomial A(x) represented by Expression (4) by the generator polynomial G(x) is represented by Expression (7); therefore, the calculation is a “linear calculation”. Namely, a remainder calculated by cumulatively adding remainders, which are obtained through the remainder calculation using the generator polynomial for each of the bit positions as in the second related technology, is equal to a remainder calculated by dividing a cumulative addition result of the remainders at the respective bit positions by the generator polynomial.

$$\begin{matrix}R ( x ) = A ( x ) mod G ( x ) \\ = ( {\sum }_{n = 0}^{K - 1} {a}_{n} {x}^{n} ) mod G ( x ) \\ = {\sum }_{n = 0}^{K - 1} {a}_{n} ( {x}^{n} mod G ( x ) )\end{matrix} \qquad ( 7 )$$

Therefore, in a first embodiment, the order of execution of the remainder calculation and the cumulative addition in the second related technology is reversed. Specifically, in the first embodiment, a cumulative addition result of the remainders at the respective bit positions is first obtained, and a final remainder is subsequently calculated by dividing the cumulative addition result by the generator polynomial. Consequently, in the first embodiment, the number of the remainder calculations is reduced as compared to the second related technology.

Further, in the first embodiment, the remainder is obtained by a vector operation using a matrix. The remainder calculation to obtain the remainder R(x) is a linear calculation as represented by Expression (7); therefore, a vector operation to obtain the remainder R(x) is represented by a linear transformation.

Specifically, when a remainder Rₙ(x) of a monomial is represented by Expression (8), a remainder vector rₙ equivalent to Expression (8) is represented by Expression (9).

Rₙ(x)=xⁿ mod G(x)=r_{nL-1}x^{L-1}+ . . . +rₙ₁x+rₙ₀ (8)

rₙ=Gᵣeₙ rₙ=(rₙ₀,rₙ₁, . . . ,r_{nL-1})^{T} eₙ=(0, . . . 0,1,0 . . . ,0)^{T} (9)

Here, Gᵣ in Expression (9) is represented by Expression (10) by using remainders r₀, r₁, . . . r_{K-1} corresponding to n=0, 1, . . . , K−1, respectively.

Gᵣ=[r₀,r₁, . . . ,r_{K-1}] (10)

Therefore, assuming that a vector r corresponding to R(x) is r=(r₀, r₁, . . . , r_{L}), the remainder vector r corresponding to R(x) represented by Expression (7) is represented by Expression (11).

$$r = {G}_{r} a = {G}_{r} = ( {\sum }_{n = 0}^{K - 1} {a}_{n} {e}_{n} ) = {\sum }_{n = 0}^{K - 1} {a}_{n} ( {G}_{r} {e}_{n} ) = {\sum }_{n = 0}^{K - 1} {a}_{n} {r}_{n} \qquad ( 11 )$$

Incidentally, if Expression (11) is generalized with respect to a bit string aₙᵢ that is randomly input, the remainder vector r is represented by Expression (12).

$$r = {\sum }_{i = 0}^{K - 1} {a}_{{n}_{i}} {r}_{{n}_{i}} \qquad ( 12 )$$

Configuration of Error Detecting Device

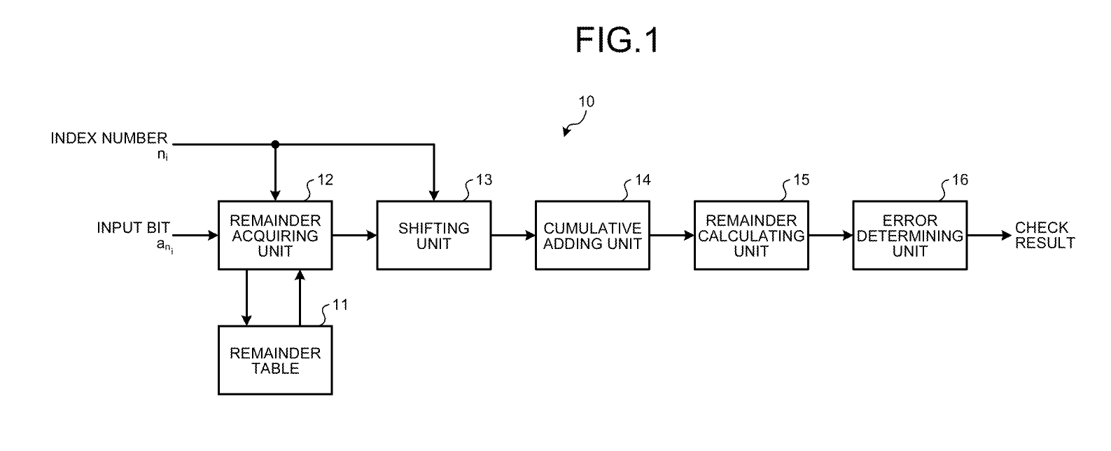

FIG. 1 is a functional block diagram illustrating an example of the error detecting device of the first embodiment. In FIG. 1, an error detecting device 10 includes a remainder table 11, a remainder acquiring unit 12, a shifting unit 13, a cumulative adding unit 14, a remainder calculating unit 15, and an error determining unit 16.

The remainder acquiring unit 12 receives randomly-input bits aₙᵢ of an input bit string one by one, and receives input of index numbers nᵢ (i=0, 1, 2, . . . , K−1) indicating normal bit positions of the respective bits aₙᵢ. The “normal bit positions” are the positions of the respective bits in one block before a sequence of the bits of the information bit string of the one block is randomized.

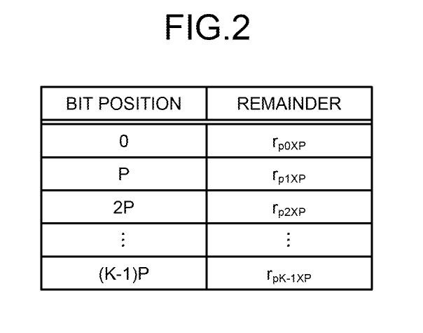

The remainder table 11 stores therein only remainders r_{pi×P} corresponding to respective bit positions of “pᵢ×P” (pᵢ=0, 1, 2, . . . , K−1) at a predetermined bit interval “P” among L-bit remainders rₙᵢ corresponding to normal bit positions nᵢ of the respective bits aₙᵢ (corresponding to the remainder vector rₙ represented by Expression (9)). In this regard, P=2^{m}, that is, P is a power of 2. FIG. 2 is a diagram illustrating an example of the remainder table of the first embodiment. For example, as illustrated in FIG. 2, the remainder table 11 stores therein remainders r_{p0×P}, r_{p1×P}, r_{p2×P}, . . . , r_{pK-1×P} in association with the bit positions of 0, P, 2P, . . . , (K−1)P, respectively. Incidentally, the remainders rₙᵢ corresponding to the normal bit positions nᵢ of the respective bits aₙᵢ can be calculated in advance according to Expression (8) and Expression (9). Namely, the remainder table 11 stores therein only remainders corresponding to bit positions p×P (p is an integer equal to or greater than 0) at the predetermined bit interval P among the remainders Rₙ(x) of divisions of monomials xⁿ, which correspond to the respective bit positions in the bit string represented by the polynomial A(x), by the generator polynomial G(x).

The remainder acquiring unit 12 acquires L-bit remainders from the remainder table 11 on the basis of the index numbers nᵢ of bits of 1 (that is, bits other than 0) among the input bits aₙᵢ. The remainder acquiring unit 12 does not acquire remainders of the bits of 0 among the input bits aₙᵢ. The remainder acquiring unit 12 resolves the index number nᵢ into “pᵢ×P+qᵢ” (qᵢ=0, 1, 2, . . . , P−1), acquires a remainder corresponding to “pᵢ×P” from the remainder table 11, and outputs the remainder to the shifting unit 13. Namely, the remainder acquiring unit 12 acquires, from the remainder table 11, a remainder corresponding to p×P of p×P+q (q is an integer equal to or greater than 0 and smaller than P) representing the normal bit position of a bit of 1 among the bits in an input bit string.

Incidentally, assuming that an arbitrary index number n is represented as a sum of two integers of Q and q such that “n=Q+q”, the remainder Rₙ(x) with respect to a monomial is represented by Expression (13).

Rₙ(x)=xⁿ mod G(x)=x^{Q+q} mod G(x)=((x^{Q} mod G(x))×x^{q})mod G(x) (13)

Further, a multiplication of the polynomial A(x) by a monomial x^{q} is equal to addition of q to a power of each term in A(x) as represented by Expression (14).

x^{q}A(x)=x^{q}(a_{N}x^{N}+ . . . +a₁x+a₀)=a_{N}x^{N-q}+ . . . +a₁x^{1+q} a₀x^{q} (14)

A vector representation in Expression (14) corresponds to a_{q}˜, which is obtained by shifting the index a by q, as represented by Expression (15).

$$\begin{matrix}a = ( {a}_{0} , {a}_{1} , … {a}_{N - 1} ) \to {\tilde{a}}_{q} \\ = ( \underbrace{0 , … , 0}_{q} , {a}_{0} , {a}_{1} , … , {a}_{N - 1} , 0 , … , 0 )\end{matrix} \qquad ( 15 )$$

Therefore, a remainder vector r_{Q+q} equivalent to the remainder Rₙ(x) represented by Expression (13) is represented by Expression (16) by using a shift vector r˜_{Q+q}, which is obtained by shifting a reference remainder vector r_{Q} by q, and by using Gᵣ represented by Expression (10).

r_{Q-q}=Gᵣ\tilde{r}_{Q-q} (16)

Therefore, the index number nᵢ is input to the shifting unit 13. The shifting unit 13 resolves the input index number nᵢ into “pᵢ×P+qᵢ”, shifts the remainder r_{pi×P} acquired by the remainder acquiring unit 12 by qᵢ bits, and outputs a shift result to the cumulative adding unit 14.

The cumulative adding unit 14 cumulatively adds K shift results (i=0, 1, 2, . . . , K−1) sequentially input from the shifting unit 13, and outputs a cumulative addition result to the remainder calculating unit 15. Specifically, the cumulative adding unit 14 employs, as objects to be cumulatively added, the shift results that the shifting unit 13 obtains by shifting the remainders r_{p×P} acquired by the remainder acquiring unit 12 by q bits. The remainder acquiring unit 12 acquires remainders of only bits of 1 among the input bits aₙᵢ but does not acquire remainders of bits of 0 as described above. Therefore, the cumulative adding unit 14 calculates a cumulative addition result, in which all of the shift results corresponding to all of the bits of 1 among the bits in the input bit string are cumulatively added.

The remainder calculating unit 15 performs a remainder calculation to calculate a remainder R(x) (corresponding to the remainder vector r represented by Expression (11)) by dividing the cumulative addition result obtained by the cumulative adding unit 14 by the generator polynomial G(x), and outputs a calculated remainder to the error determining unit 16. Namely, the error detecting device 10 performs a remainder calculation only once when detecting an error in an information bit string of one block.

The error determining unit 16 determines that “there is no error” in the input bit string when the remainder calculated by the remainder calculating unit 15 is “0”, and determines that “there is an error” in the input bit string when the remainder calculated by the remainder calculating unit 15 is “other than 0”. Then, the error determining unit 16 outputs, as a check result, a value corresponding to a determination result. For example, the error determining unit 16 outputs “0” when determining that “there is no error” in the input bit string, and outputs “1” when determining that “there is an error” in the input bit string.

Process by Error Detecting Device

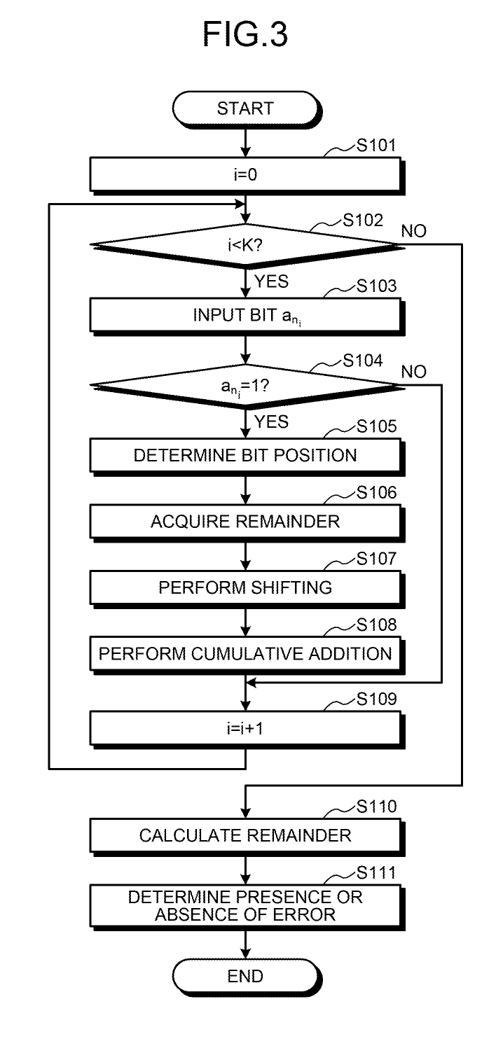

FIG. 3 is a flowchart for explaining a process performed by the error detecting device of the first embodiment. The flowchart illustrated in FIG. 3 starts when the first bit of an input bit string is input to the error detecting device 10.

First, the error detecting device 10 resets a value of a counter i to 0 (Step S101).

Subsequently, the error detecting device 10 determines whether the value of i is smaller than K (Step S102).

If the value of i is smaller than K (YES at Step S102), a bit aₙᵢ and an index number nᵢ are input to the error detecting device 10 (Step S103). The bit aₙᵢ is input in a random order.

Subsequently, the error detecting device 10 determines whether a value of the bit aₙᵢ is 1 (Step S104).

If the value of the bit aₙᵢ is not 1, that is, if the value is 0 (NO at Step S104), processes from Steps S105 to S108 are not performed, and process control proceeds to Step S109.

If the value of the bit aₙᵢ is 1 (YES at Step S104), the error detecting device 10 resolves the index number nᵢ into “pᵢ×P+qᵢ” and determines a bit position of “pᵢ×P” (Step S105).

Subsequently, the error detecting device 10 acquires a remainder r_{pi×P} corresponding to the bit position pᵢ×P determined at Step S105 (Step S106).

Then, the error detecting device 10 obtains a shift result r˜^{(qi)}_{pi×P} by shifting the remainder r_{pi×P} acquired at Step S106 by qᵢ bits as represented by Expression (17) (Step S107). Namely, the error detecting device 10 embeds qᵢ zeros at the head of the remainder vector r_{pi×P} to transform the remainder vector r_{pi×P} into the remainder vector r˜^{(qi)}_{pi×P}.

$${r}_{{p}_{i} \times P} \to {\tilde{r}}_{{p}_{i} \times P}^{( {q}_{i} )} = ( \underbrace{0 , … , 0}_{{q}_{i}} , {r}_{p \times P , 0} , {r}_{p \times P , 1} , … , , {r}_{p \times P , L - 1} , 0 , … , 0 ) \qquad ( 17 )$$

Subsequently, the error detecting device 10 cumulatively adds the shift result obtained at Step S107, in accordance with Expression (18) (Step S108).

\tilde{r}=\tilde{r}+\tilde{r}ₚ_{ᵢ}_{×P}^{(q}^{ᵢ}⁾ (18)

Then, the error detecting device 10 increments the value i of the counter by one (Step S109), and the control returns to Step S102.

If the value of i becomes equal to or greater than K by repetition of the processes from Steps S103 to S109 K times (NO at Step S102), the error detecting device 10 calculates a remainder vector r by performing a remainder calculation on a cumulative addition result r˜ in accordance with Expression (19) (Step S110). Expression (19) represents a remainder calculation using a matrix F instead of a matrix Gᵣ. F in Expression (19) is a submatrix formed by extracting parts of the matrix Gᵣ, and an extraction size is equal to the size of the shift vector r˜_{Q+q}. The maximum value of a shift amount is defined in advance; therefore, by setting the size of the shift vector to the maximum value of the shift amount, it is possible to fix the matrix F regardless of the shift amount.

r=F\tilde{r} (19)

Components in Expression (19) are represented by Expression (20).

$$\{ \begin{matrix}{r}_{0} = {f}_{00} {\tilde{r}}_{0} + {f}_{01} {\tilde{r}}_{1} + … + {f}_{0 , L + P - 2} {\tilde{r}}_{L + P - 2} \\ {r}_{1} = {f}_{10} {\tilde{r}}_{0} + {f}_{11} {\tilde{r}}_{1} + … + {f}_{1 , L + P - 2} {\tilde{r}}_{L + P - 2} \\ ⋮ \\ {r}_{L - 1} = {f}_{L - 10} {\tilde{r}}_{0} + {f}_{L - 11} {\tilde{r}}_{1} + … + {f}_{L - 1 , L + P - 2} {\tilde{r}}_{L + P - 2}\end{matrix} \qquad ( 20 )$$

Subsequently, the error detecting device 10 determines presence or absence of an error in the input bit string formed of bits aₙ₀ to a_{nK-1} on the basis of the remainder vector r calculated at Step S110 (Step S111), and the process ends. Specifically, if all of r₀ to r_{L-1} represented by Expression (20) are 0, the error detecting device 10 determines that “there is no error” in the input bit string. In contrast, if any of r₀ to r_{L-1} represented by Expression (20) is 1, the error detecting device 10 determines that “there is an error” in the input bit string.

As described above, the error detecting device 10 first obtains a cumulative addition result of remainders at the respective bit positions, and subsequently divides the cumulative addition result by the generator polynomial to calculate a final remainder used to determine presence or absence of an error. In this operation, the error detecting device 10 performs a remainder calculation only once when detecting an error in an information bit string of one block. Therefore, according to the first embodiment, it is possible to reduce a processing load for error detection.

Further, it is preferable that the error detecting device 10 performs the remainder calculation by using the matrix F instead of the matrix Gᵣ. The matrix F is a submatrix of the matrix Gᵣ. With this operation, it is possible to reduce an operation amount of a matrix operation, enabling to further reduce the processing load for error detection.

### [b] Second Embodiment

### Operation of Error Detecting Device

If a transformation matrix G is employed, which is used to obtain a remainder rₙ₊₁ corresponding to an index number n+1 from a remainder rₙ corresponding to an arbitrary index number n, the remainder rₙ₊₁ is represented by Expression (21). With the transformation matrix G, shifting of the remainder rₙ and a remainder calculation on a shift result are collectively performed to calculate the remainder rₙ₊₁.

rₙ₊₁=Grₙ (21)

If the index number n is resolved into “p×P+q”, Expression (21) is represented by Expression (22).

rₙ=r_{p×P+q}=G^{q}r_{p×P} (22)

Therefore, in a second embodiment, remainders corresponding to all of the index numbers are calculated according to Expression (22). A transformation matrix G^{q} in Expression (22) is an L×L submatrix of the matrix F in Expression (19). Therefore, when the matrix F in Expression (19) is represented by Expression (23), the transformation matrix G^{q} is represented by Expression (24).

F=└f₀,f₁, . . . ,fₚ₊₁₋₂┘ (23)

G^{q}=[f_{q}, . . . ,f_{q+L-1}] (24)

In this case, the remainder rₙ is represented by Expression (25) by using a remainder clearly indicating the number of shifts and by using the matrix F.

rₙ=F\tilde{r}_{p×P}^{(q)} (25)

Transformation between r˜^{(q)}_{p×P} and r_{p×P} is represented by a matrix operation as represented by Expression (26).

$${\tilde{r}}_{p \times P}^{( q )} = {S}^{( q )} {r}_{p \times P} \\ {S}^{( q )} = [ \begin{matrix}{O}_{q \times L} \\ {I}_{L} \\ {O}_{( P + L - q - 1 ) \times L}\end{matrix} ] \qquad ( 26 )$$

Therefore, the remainder rₙ is represented by Expression (27) by using the transformation matrix G^{q}.

$${r}_{n} = {FS}^{( q )} {r}_{p \times P} \\ {G}^{q} = {FS}^{( q )} = F [ \begin{matrix}{O}_{q \times L} \\ {I}_{L} \\ {O}_{( P + L - q - 1 ) \times L}\end{matrix} ] = [ {f}_{q} , … , {f}_{q + L - 1} ] \qquad ( 27 )$$

Configuration of Error Detecting Device

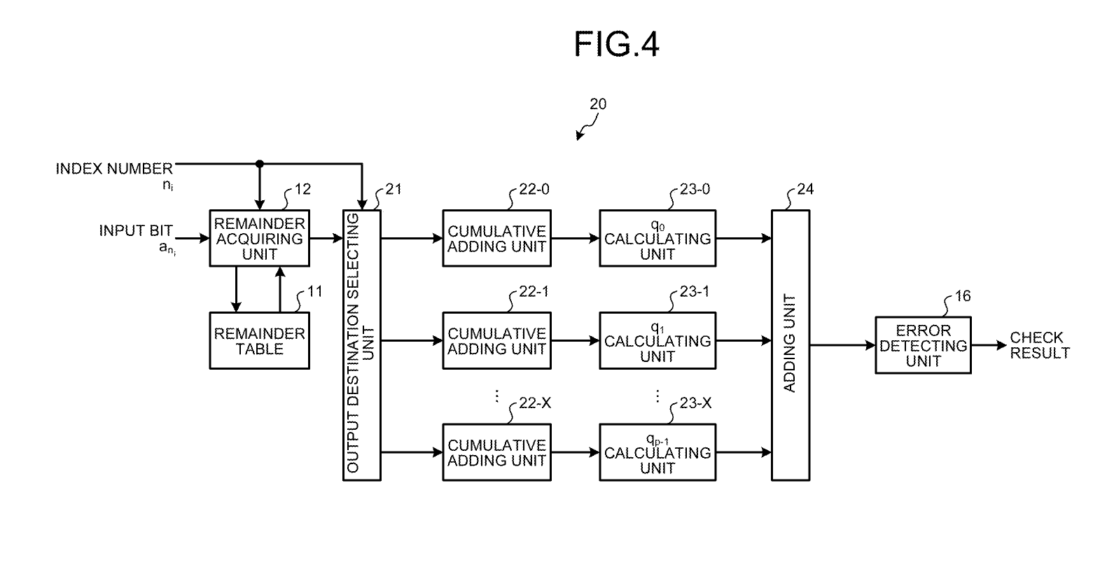

FIG. 4 is a functional block diagram illustrating an example of an error detecting device of the second embodiment. In FIG. 4, an error detecting device 20 includes the remainder table 11, the remainder acquiring unit 12, an output destination selecting unit 21, and cumulative adding units 22-0 to 22-X. The error detecting device 20 further includes a q₀ calculating unit 23-0 to a q_{P-1} calculating unit 23-X, an adding unit 24, and the error determining unit 16.

The remainder acquiring unit 12 acquires, from the remainder table 11, a remainder corresponds to “pᵢ×P” of only a bit of 1 among the input bits aₙᵢ, and outputs the remainder to the output destination selecting unit 21, similarly to the first embodiment.

The output destination selecting unit 21 receives input of the index number nᵢ. The output destination selecting unit 21 resolves the input index number nᵢ into “pᵢ×P+qᵢ” (qᵢ=0, 1, 2, . . . , P−1), and selects an output destination of the remainder in accordance with qᵢ. Specifically, the output destination selecting unit 21 outputs the remainder to the cumulative adding unit 22-0 when qᵢ=0, outputs the remainder to the cumulative adding unit 22-1 when qᵢ=1, and outputs the remainder to the cumulative adding unit 22-X when qᵢ=P−1.

Therefore, the cumulative adding unit 22-0 cumulatively adds remainders corresponding to qᵢ=0 for respective pᵢ, the cumulative adding unit 22-1 cumulatively adds remainders corresponding to qᵢ=1 for respective pᵢ, and the cumulative adding unit 22-X cumulatively adds remainders corresponding to qᵢ=P−1 for respective pᵢ. Namely, the cumulative adding units 22-0 to 22-X cumulatively adds the remainders acquired by the remainder acquiring unit 12 for respective q to obtain cumulative addition results for the respective q. The cumulative adding unit 22-0 outputs a cumulative addition result corresponding to qᵢ=0 to the q₀ calculating unit 23-0, and the cumulative adding unit 22-1 outputs a cumulative addition result corresponding to qᵢ=1 to the q₁ calculating unit 23-1. Further, the cumulative adding unit 22-X outputs a cumulative addition result corresponding to qᵢ=P−1 to the q_{P-1} calculating unit 23-X.

The q₀ calculating unit 23-0 performs a remainder calculation to obtain a remainder by dividing a shift result, which is obtained by shifting the cumulative addition result corresponding to qᵢ=0 by a bit of qᵢ=0 (that is, the cumulative addition result corresponding to qᵢ=0), by the generator polynomial G(x), and outputs the calculated remainder to the adding unit 24. The q₁ calculating unit 23-1 performs a remainder calculation to obtain a remainder by dividing a shift result, which is obtained by shifting the cumulative addition result corresponding to qᵢ=1 by a bit of qᵢ=1, by the generator polynomial G(x), and outputs the calculated remainder to the adding unit 24. Further, the q_{P-1} calculating unit 23-X performs a remainder calculation to obtain a remainder by dividing a shift result, which is obtained by shifting the cumulative addition result corresponding to qᵢ=P−1 by a bit of qᵢ=P−1, by the generator polynomial G(x), and outputs the calculated remainder to the adding unit 24. Namely, each of the q₀ calculating unit 23-0 to the Q_{P-1} calculating unit 23-X performs, for each q, the remainder calculation to obtain a remainder of a division of the shift result, which is obtained by shifting the cumulative addition result of each q by q bits, by the generator polynomial.

Further, each of the q₀ calculating unit 23-0 to the q_{P-1} calculating unit 23-X performs, for each q, a shift process of shifting the cumulative addition result of each q by q bits and a remainder calculation to obtain a remainder by dividing the shift result by the generator polynomial, in accordance with Expression (22) by using the transformation matrix G^{q} that is a submatrix of the matrix F. Namely, each of the q₀ calculating unit 23-0 to the q_{P-1} calculating unit 23-X uses the transformation matrix G^{q} for collectively performing shift and the remainder calculation.

The adding unit 24 adds all of the remainders calculated by the q₀ calculating unit 23-0 to the q_{P-1} calculating unit 23-X to obtain the remainder R(x) (corresponding to the remainder vector r represented by Expression (11)), and outputs the calculated remainder to the error determining unit 16. Namely, the adding unit 24 adds all of the remainders corresponding to all q of 0 to P−1 to obtain the remainder R(x).

Process by Error Detecting Device

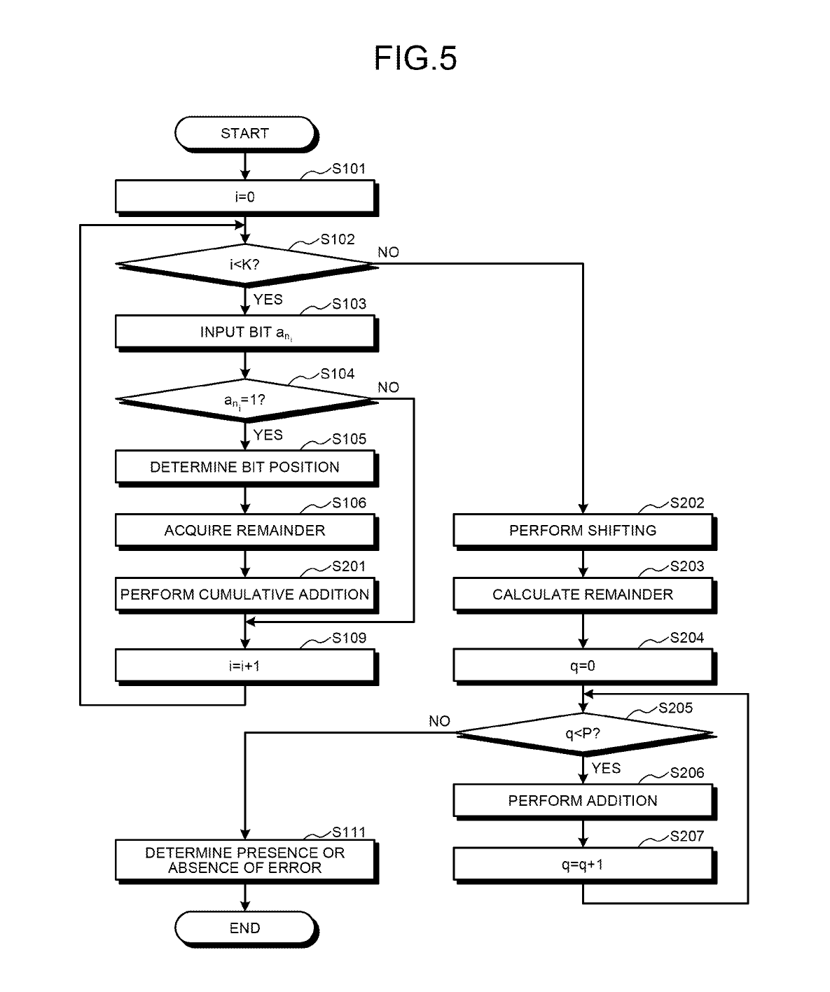

FIG. 5 is a flowchart for explaining a process performed by the error detecting device of the second embodiment. The flowchart illustrated in FIG. 5 starts when the first bit of an input bit string is input to the error detecting device 20. In FIG. 5, processes from Steps S101 to S106, S109, and S111 are the same as those of the first embodiment (FIG. 3), and therefore, explanation thereof will be omitted.

At Step S201, the error detecting device 20 cumulatively adds, for each qᵢ, the remainders r_{pi×P} acquired at Step S106 in accordance with Expression (28).

r^{(q}^{ᵢ}⁾=r^{(q}^{ᵢ}⁾+rₚ_{ᵢ}_{×P} (28)

Specifically, in the series of the processes from Steps S103 to S201, and S109, a cumulative addition represented by Expression (29) is performed, and a cumulative addition result r^{(q)} for each q is calculated.

$${r}^{( q )} = {\sum }_{i : {q}_{i} = q} {a}_{{p}_{i} \times P + {q}_{i}} {r}_{{p}_{i} \times P} \qquad ( 29 )$$

If the value of i becomes equal to or greater than K by repetition of the processes from Steps S103 to S201, and S109 K times (NO at Step S102), the error detecting device 20 collectively performs processes at Step S202 and S203. Specifically, the error detecting device 20 performs a shift process of shifting the cumulative addition result of each q by q bits and a remainder calculation to obtain a remainder by dividing the shift result by the generator polynomial, in accordance with Expression (30) by using the transformation matrix G^{q}, thereby obtaining a remainder r^{[q]} for each q (Steps S202 and S203).

r^{[q]}=G^{q}r^{(q)} (30)

Components in Expression (30) are represented by Expression (31).

$$\{ \begin{matrix}{r}_{0}^{[ q ]} = {g}_{00} {r}_{0}^{( q )} + {g}_{01} {r}_{1}^{( q )} + … + {g}_{0 , L - 1} {r}_{L - 1}^{( q )} \\ {r}_{1}^{[ q ]} = {g}_{10} {r}_{0}^{( q )} + {g}_{11} {r}_{1}^{( q )} + … + {g}_{1 , L - 1} {r}_{L - 1}^{( q )} \\ ⋮ \\ {r}_{L - 1}^{[ q ]} = {g}_{L - 1 , 0} {r}_{0}^{( q )} + {g}_{L - 11} {r}_{1}^{( q )} + … + {g}_{L - 1 , L - 1} {r}_{L - 1}^{( q )}\end{matrix} \qquad ( 31 )$$

Subsequently, the error detecting device 20 performs processes from Step S204 to S207 to perform an addition represented by Expression (32) to calculate the remainder vector r.

$$r = {\sum }_{q = 0}^{P - 1} {r}^{[ q ]} \qquad ( 32 )$$

Specifically, the error detecting device 20 resets a value of a counter q to 0 (Step S204).

Subsequently, the error detecting device 20 determines whether the value of q is smaller than P (Step S205).

If the value of q is smaller than P (YES at Step S205), the error detecting device 20 adds r^{[q]} in accordance with Expression (33) corresponding to the value of q (Step S206).

r=r+r^{[q]} (33)

Subsequently, the error detecting device 20 increments the value of the counter q by one (Step S207), and the process returns to Step S205.

Then, if the value of q becomes equal to or greater than P by repetition of the processes at Steps S206 and S207 P times (NO at Step S205), the error detecting device 20 determines presence or absence of an error in the input bit string formed of bits aₙ₀ to a_{nK-1}, on the basis of the remainder vector r that is an addition result obtained at Step S206 (Step S111), and the process ends.

As described above, the error detecting device 20 first obtains, for each q, a cumulative addition result of remainders at all of the bit positions, and subsequently performs, for each q, a remainder calculation to obtain a remainder by dividing a shift result, which is obtained by shifting the cumulative addition result of each q by q bits, by the generator polynomial. Then, all of the remainders corresponding to all q of 0 to P−1 are added, so that a final remainder used to determine presence or absence of an error is calculated. With this operation, in a calculation for each q, a remainder calculation is performed only once with respect to each q. q is 0 to P−1. Therefore, the error detecting device 20 performs the remainder calculation only P times at a maximum when detecting an error in an information bit string of one block. Consequently, according to the second embodiment, it is possible to reduce a processing load for error detection.

Further, the error detecting device 20 collectively performs a shift process of shifting the cumulative addition result of each q by q bits and a remainder calculation to obtain a remainder by dividing the shift result by the generator polynomial, by using the transformation matrix G^{q}. The transformation matrix G^{q} is a submatrix of the matrix F, and the matrix F is a submatrix of the matrix Gᵣ. With this operation, it is possible to reduce an operation amount of a matrix operation, enabling to further reduce the processing load for error detection.

### [c] Third Embodiment

### Operation of Error Detecting Device

Expression (32) can be transformed into Expression (34).

$$r = {\sum }_{q = 0}^{P - 1} {r}^{[ q ]} = {\sum }_{q = 0}^{P - 1} {G}^{q} {r}^{( q )} \qquad ( 34 )$$

Specifically, calculations performed by the q₀ calculating unit 23-0 to the q_{P-1} calculating unit 23-X and the adding unit 24 in the second embodiment are calculations of powers of G. Therefore, the calculations by the q₀ calculating unit 23-0 to the q_{P-1} calculating unit 23-X and the adding unit 24 in the second embodiment may be performed by using a fast Fourier transform (FFT) algorithm.

An example of the FFT algorithm for a general power series will be described below.

A power series A(x) to be obtained is defined by Expression (35). N=2^{m}. In general, extension is performed when N is represented by a multiplication of factors of powers of a plurality of prime numbers.

$$A ( x ) = {\sum }_{n = 0}^{N - 1} {a}_{n} {x}^{n} \qquad ( 35 )$$

As represented by Expressions (36) and (37), with regard to a sum of the series, a sum of two items are obtained in the descending order of index.

$$\begin{matrix}\begin{matrix}A ( x ) = {\sum }_{k = 0}^{N / 2 - 1} ( {a}_{2 k} {x}^{2 k} + {a}_{2 k + 1} {x}^{2 k + 1} ) \\ = {\sum }_{k = 0}^{N / 2 - 1} ( {a}_{2 k} + {a}_{2 k + 1} x ) {x}^{2 k} \\ = {\sum }_{k = 0}^{N / 2 - 1} {A}_{1 , k} ( x ) {{X}_{1} ( x )}^{k}\end{matrix} & ( 36 ) \\ {A}_{1 , k} ( x ) = {a}_{2 k} + {a}_{2 k + 1} x \\ {X}_{1} ( x ) = {x}^{2} & ( 37 )\end{matrix}$$

Therefore, the x-power series is represented by a power series of half the number of terms in X₁(x). Therefore, repetition of Expressions (36) and (37) i times is given by Expressions (38) and (39). When i=m, the number of items becomes one, and a final calculation result in the FET algorithm is obtained.

$$\begin{matrix}A ( x ) = {\sum }_{k = 0}^{N / {2}^{i} - 1} {A}_{i , k} ( x ) {{X}_{i} ( x )}^{k} & ( 38 ) \\ {A}_{i , k} ( x ) + {A}_{i - 1 , 2 k} ( x ) + {A}_{i - 1 , 2 k - 1} ( x ) {X}_{i - 1} ( x ) \\ {X}_{i} ( x ) = {{X}_{i - 1} ( x )}^{2} = {x}^{{2}^{i}} & ( 39 )\end{matrix}$$

Configuration of Error Detecting Device

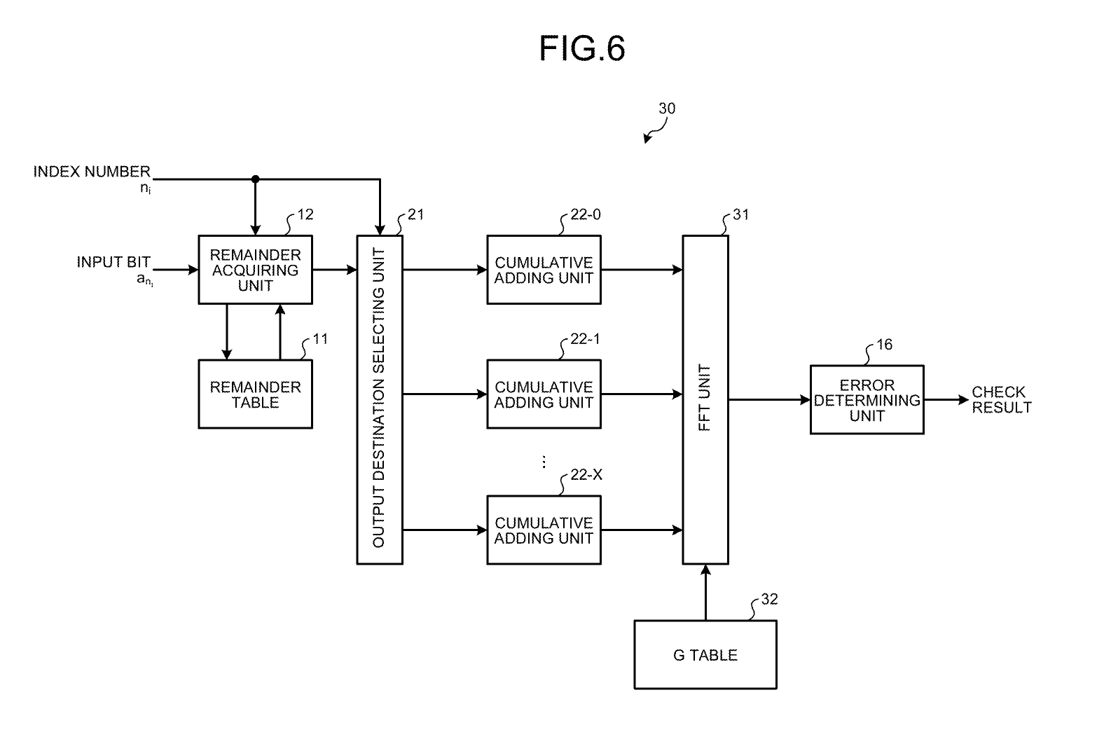

FIG. 6 is a functional block diagram illustrating an example of an error detecting device of a third embodiment. In FIG. 6, an error detecting device 30 includes the remainder table 11, the remainder acquiring unit 12, the output destination selecting unit 21, and the cumulative adding units 22-0 to 22-X. The error detecting device 30 further includes an FFT unit 31, a G table 32, and the error determining unit 16. Namely, in the error detecting device 30, the q₀ calculating unit 23-0 to the q_{P-1} calculating unit 23-X and the adding unit 24 of the error detecting device 20 of the second embodiment (FIG. 4) are replaced with the FFT unit 31.

The G table 32 stores therein G^{q} (q=0 to P−1) represented in Expression (34).

The FFT unit 31 performs calculations similar to those performed by the q₀ calculating unit 23-0 to the q_{P-1} calculating unit 23-X and the adding unit 24 in the second embodiment, with respect to a cumulative addition result of each q by using G^{q} stored in the G table 32 in accordance with the FET algorithm as described above. Through the calculations according to the FET algorithm, the remainder R(x) (corresponding to the remainder vector r represented by Expression (34)) used for determination by the error determining unit 16 is calculated.

Process by Error Detecting Device

A flowchart of the third embodiment is obtained by replacing the processes from Steps S202 to S207 in the flowchart of the second embodiment (FIG. 5) with calculations using the FET algorithm according to Expression (34).

As described above, the error detecting device 30 performs the same calculations as those performed by the q₀ calculating unit 23-0 to the q_{P-1} calculating unit 23-X and the adding unit 24 in the second embodiment, by using the FET algorithm. With this operation, it is possible to perform a remainder calculation to obtain a remainder by dividing a shift result, which is obtained by shifting the cumulative addition result of each q by q bits, by a generator polynomial q, and add all of the remainders corresponding to all q of 0 to P−1, at high speed.

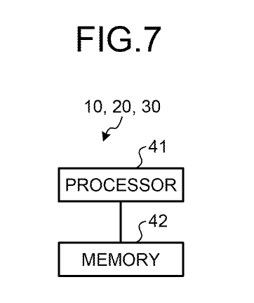

### [d] Other Embodiments

[1] The error detecting devices 10, 20, and 30 of the above described embodiments are realized by a hardware configuration as described below. FIG. 7 is a diagram illustrating a hardware configuration example of the error detecting device. As illustrated in FIG. 7, each of the error detecting devices 10, 20, and 30 includes, as hardware components, a processor 41 and a memory 42. Examples of the processor 41 include a central processing unit (CPU), a digital signal processor (DSP), and a field programmable gate array (FPGA). Each of the error detecting devices 10, 20, and 30 may include a large scale integrated circuit (LSI) including the processor 41 and peripheral circuits. Examples of the memory 42 include a random access memory (RAM), such as a synchronous dynamic random access memory (SDRAM), a read only memory (ROM), and a flash memory. The remainder acquiring unit 12, the shifting unit 13, the cumulative adding unit 14, the remainder calculating unit 15, the error determining unit 16, the output destination selecting unit 21, the cumulative adding units 22-0 to 22-X, the q₀ calculating unit 23-0 to the q_{P-1} calculating unit 23-X, the adding unit 24, and the FFT unit 31 are realized by the processor 41. The remainder table 11 and the G table 32 are realized by the memory 42.

[2] Each of the processes performed by the error detecting devices 10, 20, and 30 as described above may be performed by causing the processor 41 to execute a program. For example, a program corresponding to each of the processes performed by the error detecting devices 10, 20, and 30 as described above may be stored in the memory 42, and the processor 41 reads the programs corresponding to the respective processes from the memory 42 and executes the programs.

According to an aspect of the disclosed technology, it is possible to reduce a processing load for error detection.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An error detecting device comprising:
a memory that stores therein first remainders corresponding to a plurality of bit positions p×P (p is an integer equal to or greater than zero) at a predetermined bit interval P among all of remainders obtained by dividing monomials, which correspond to the respective bit positions in a bit string represented by a polynomial, by a generator polynomial for generating an error detecting code; and
a processor configured to
receive each of bits of an input bit string,
receive normal bit positions of the respective bits,
acquire, from the memory, the first remainders corresponding to p×P of p×P+q (q is an integer equal to or greater than zero and smaller than P) representing the normal bit positions of bits of 1 among all of the bits of the input bit string,
obtain a cumulative addition result by shifting each of the acquired first remainders by q bits to obtain shift results, and then cumulatively adding all of the shift results corresponding to all of the bits of 1 among all of the bits of the input bit string,
perform a remainder calculation to obtain a second remainder by dividing the cumulative addition result by the generator polynomial, and
determine presence or absence of an error in the input bit string on the basis of the second remainder.

2. An error detecting device comprising:
a memory that stores therein first remainders corresponding to a plurality of bit positions p×P (p is an integer equal to or greater than zero) at a predetermined bit interval P among all of remainders obtained by dividing monomials, which correspond to the respective bit positions in a bit string represented by a polynomial, by a generator polynomial for generating an error detecting code; and
a processor configured to
receive each of bits of an input bit string,
receive normal bit positions of the respective bits,
acquire, from the memory, the first remainders corresponding to p×P of p×P+q (q is an integer equal to or greater than zero and smaller than P) representing the normal bit positions of bits of 1 among all of the bits of the input bit string,
perform, for each q, a remainder calculation to obtain a second remainder by cumulatively adding the acquired first remainders for each q to obtain a cumulative addition result for each q, shifting the cumulative addition result by q bits to obtain a shift result, and dividing the shift result by the generator polynomial,
obtain a third remainder by adding all of the second remainders corresponding to all q, and
determine presence or absence of an error in the input bit string on the basis of the third remainder.

3. The error detecting device according to claim 2, wherein the processor collectively performs the shifting for each q and the remainder calculation for each q by using a submatrix of a matrix used for the remainder calculation using the generator polynomial.

4. The error detecting device according to claim 2, wherein the processor performs the shifting for each q, the remainder calculation for each q, and the adding of all of the second remainders, by using a fast Fourier transform algorithm.

5. An error detecting method performed by an error detecting device including a memory that stores therein first remainders corresponding to a plurality of bit positions p×P (p is an integer equal to or greater than zero) at a predetermined bit interval P among all of remainders obtained by dividing monomials, which correspond to the respective bit positions in a bit string represented by a polynomial, by a generator polynomial for generating an error detecting code, the error detecting method comprising:
acquiring, from the memory, the first remainders corresponding to p×P of p×P+q (q is an integer equal to or greater than zero and smaller than P) representing normal bit positions of bits of 1 among all of bits of an input bit string;
obtaining a cumulative addition result by shifting each of the acquired first remainders by q bits to obtain shift results, and then cumulatively adding all of the shift results corresponding to all of the bits of 1 among all of the bits of the input bit string;
performing a remainder calculation to obtain a second remainder by dividing the cumulative addition result by the generator polynomial; and
determining presence or absence of an error in the input bit string on the basis of the second remainder.

6. An error detecting method performed by an error detecting device including a memory that stores therein first remainders corresponding to a plurality of bit positions p×P (p is an integer equal to or greater than zero) at a predetermined bit interval P among all of remainders obtained by dividing monomials, which correspond to the respective bit positions in a bit string represented by a polynomial, by a generator polynomial for generating an error detecting code, the error detecting method comprising:
acquiring, from the memory, the first remainders corresponding to p×P of p×P+q (q is an integer equal to or greater than zero and smaller than P) representing normal bit positions of bits of 1 among all of bits of an input bit string;
performing, for each q, a remainder calculation to obtain a second remainder by cumulatively adding the acquired first remainders for each q to obtain a cumulative addition result for each q, shifting the cumulative addition result by q bits to obtain a shift result, and dividing the shift result by the generator polynomial;
obtaining a third remainder by adding all of the second remainders corresponding to all q; and
determining presence or absence of an error in the input bit string on the basis of the third remainder.
